(19) United States
(12) Patent Application Publication
(10) Pub. No.: US 2013/0277689 A1
(43) Pub. Date: Oct. 24, 2013

(54) NIGHT VISION IMAGING SYSTEM (NVIS) COMPATIBLE LIGHT EMITTING DIODE

(71) Applicants: Eric Lemay, Laguna Niguel, CA (US); Benjamin George Phipps, Long Beach, CA (US)

(72) Inventors: Eric Lemay, Laguna Niguel, CA (US); Benjamin George Phipps, Long Beach, CA (US)

(73) Assignee: WAMCO, INC., Fountain Valley, CA (US)

(21) Appl. No.: 13/452,035

(22) Filed: Apr. 20, 2012

(51) Int. Cl. H01L 33/50; H01L 33/58; H01L 33/52

(52) U.S. Cl. 257/88; 257/98; 438/27; 257/E33.059; 257/E33.06; 257/E33.068

(57) ABSTRACT

The present disclosure is directed to an LED assembly that is compatible for use with a night vision imaging system or any other system that requires an LED with specific transmission or rejection wavelength bands. Such LEDs may emit selective wavelength bands anywhere between 400 nm and 700 nm of the electromagnetic spectrum while limiting selective wavelength bands anywhere between 700 and 1200 nanometers. In one embodiment, the LED is manufactured by coating one or more inorganic thin film optical coatings onto the LED and then protecting the LED and thin film optical coating with a resin encapsulant. In other embodiments, additional near infrared photochemical or color correcting dyes are incorporated directly into the encapsulant.

### CROSS-REFERENCE TO RELATED APPLICATIONS

Not applicable.

### STATEMENT REGARDING FEDERALLY SPONSORED RESEARCH OR DEVELOPMENT

Not applicable.

### REFERENCE TO A COMPACT DISK APPENDIX

Not applicable.

### BACKGROUND OF THE INVENTION

1. Field of the Invention

This invention relates to night vision imaging systems (NVIS), and particularly light emitting diodes (LEDs) for use with night vision imaging systems.

2. Description of Related Art

Pilot-aircraft interface is a major component of aerospace design. A pilot must be able to quickly determine flight critical information such as, but not limited to, location, altitude, engine status, and fuel level. This is especially true for pilots flying military aircraft who not only face extreme conditions, but also have additional situational awareness requirements that require the pilot's attention during night missions while wearing night vision goggles. Such requirements include, but are not limited to, weapon systems management, search and rescue and safety concerns relating to the constant awareness of other aircraft.

Moreover, many specialized civil and military aircrafts must also be able to operate at night and under extreme conditions. Military pilots often fly at night using “near infrared” sensitive “night vision” goggles which allows them to maintain proper night vision sensitivity. However, traditional instrumentation in an aircraft cockpit causes near infrared sensitive goggles to “bloom,” greatly reducing their effectiveness. As a result of the blooming effect, cockpit instrumentation lighting is usually filtered when intended to be used with night vision goggles.

Aircraft instrumentation traditionally used incandescent filament lighting. Cathode ray tube (CRT) displays have also been used to provide information to the pilot. However, aircraft are increasingly using light emitting diodes (LEDs) and active matrix liquid crystal displays (AMLCDs) to provide that functionality. LEDs, with their low weight, low power consumption, resistance to shock and vibration, long life, and reliability are quickly becoming the preferred source of cockpit illumination. Filters are often used to prevent goggle bloom, but they tend to be bulky and expensive and introduce risk of infrared light leaking out and distorting the pilot's vision when using a night vision imaging system.

More recently, LEDs integrating absorbing materials have been developed. The filtering materials have either been mechanically attached to the LED body, or in some cases, the near IR absorbing photochemistry has been directly integrated into the LED package. These newer components, while offering an integrated component without the risk of light leakage, are large in size and inefficient. The efficiency limitation is due to the characteristics of the absorbing materials which will typically have a photopic transmission of no more than 40%.

Thus, what is needed in the art is an LED package that can control its light emissions in order to function properly with a night vision imaging system without the use of a separate filter. More particularly, as the components are generally used in a confined space, such as an AMLCD backlight, there is a need for a more efficient LED component with an increased photopic output and a smaller package size ratio.

### BRIEF SUMMARY OF THE INVENTION

The present disclosure is directed to light emitting diodes (LEDs) that emit energy in the visible region of the electromagnetic spectrum while limiting emissions in the near infrared region of the electromagnetic spectrum. “Near infrared” is a term well-known in the art and generally refers to infrared light having wavelengths close to those of visible light. Specifically, it relates to the shorter wavelengths of radiation in the infrared spectrum and especially to those between 0.7 and 2.5 micrometers. The present disclosure is also directed to inorganic thin film optical coatings that are capable of suppressing near infrared light emissions and are incorporated directly into an LED assembly. The present disclosure is also directed to inorganic and/or organic dyes and pigments that are capable of suppressing near infrared light emissions and are incorporated directly into an LED assembly. The disclosure herein provides for the creation of LED assemblies that do not require additional filtering and have little to no risk of infrared light leakage, while still conforming with industry and government standards. LEDs produced in accordance with the present disclosure are compatible with pick and place soldering equipment and are designed for a solder reflow process as known in the art.

### BRIEF DESCRIPTION OF THE SEVERAL VIEWS OF THE DRAWINGS

The foregoing summary, as well as the following detailed description, will be better understood when read in conjunction with the appended drawings. For the purpose of illustration, there is shown in the drawings certain embodiments of the present disclosure. It should be understood, however, that the invention is not limited to the precise arrangements and instrumentalities shown.

In the drawings:

FIG. 1 illustrates a sheet of glass with a near IR reflecting inorganic thin film optical coating.

FIG. 2 is a graph of the transmission spectrum of an inorganic thin film optical coating in accordance with an exemplary embodiment of the present invention.

FIG. 3 illustrates a sheet of glass with a selectively treated near IR reflecting inorganic thin film optical coating;

FIG. 4 illustrates an embodiment with an inorganic thin film optical coating bonded to an LED with and without a protective lens. The resin encapsulant may or may not contain near infrared absorbers and visible color correcting dyes or pigments.

FIG. 5 depicts one embodiment of the disclosed thin film optical coating construction manufactured in accordance with the teachings of the present invention.

### DETAILED DESCRIPTION OF THE INVENTION

Before explaining at least one embodiment of the invention in detail, it is to be understood that the invention is not limited in its application to the details of construction and to the arrangements of the components set forth in the following description or illustrated in the drawings. The invention is capable of other embodiments and of being practiced and carried out in various ways. Also, it is to be understood that the phraseology and terminology employed herein are for the purpose of description and should not be regarded as limiting. It should be understood that any one of the features of the invention may be used separately or in combination with other features. Other systems, methods, features, and advantages of the invention will be or become apparent to one with skill in the art upon examination of the drawings and the detailed description. It is intended that all such additional systems, methods, features, and advantages be included within this description, be within the scope of the present invention, and be protected by the accompanying claims.

The present invention is directed to light emitting diodes (LEDs) compatible with night vision equipment, wherein the LEDs contains a near infrared suppressing inorganic thin film optical coating bonded directly to or coated on the surface of the LEDs. In some embodiments, multiple thin film optical coatings are stacked and bonded together with resin encapsulants directly to the surface of the LEDs. In at least one embodiment, inorganic or organic near infrared suppressing dyes and/or pigments are incorporated directly into the resin encapsulant used in the bonding layers, or as a protective coating on the LEDs. In other embodiments, organic near infrared suppressing dyes and/or pigments are incorporated directly into a lens or encapsulant of the LEDs. In at least one embodiment, both organic and inorganic near infrared suppressing dyes and/or pigments are incorporated directly into a lens or encapsulant of the LEDs. In at least one embodiment, visible dyes or pigments are added to control the chromaticity of the LEDs. In at least one embodiment, the LEDs emit energy between 400 and 600 nanometers (nm) of the electromagnetic spectrum while limiting energy emission between 650 and 1200 nm.

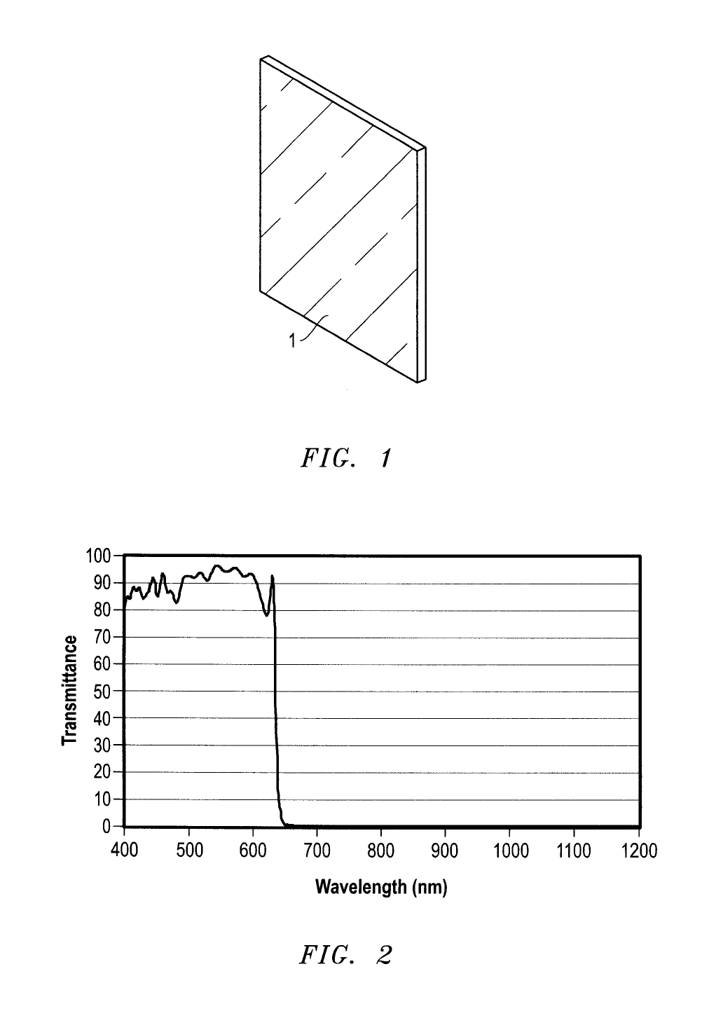

FIG. 1 illustrates a sheet of clear soda lime or glaverbel float glass with an inorganic thin film optical coating 1 applied to the surface. The inorganic thin film optical coating 1 exhibits high reflection in the red and near infrared regions of the electromagnetic spectrum. In at least one embodiment, and as illustrated in FIG. 2, the inorganic thin film optical coating 1 has a rejection band between approximately 650 nm and 1200 nm and a transmission band between approximately 400 nm and 600 nm of the electromagnetic spectrum.

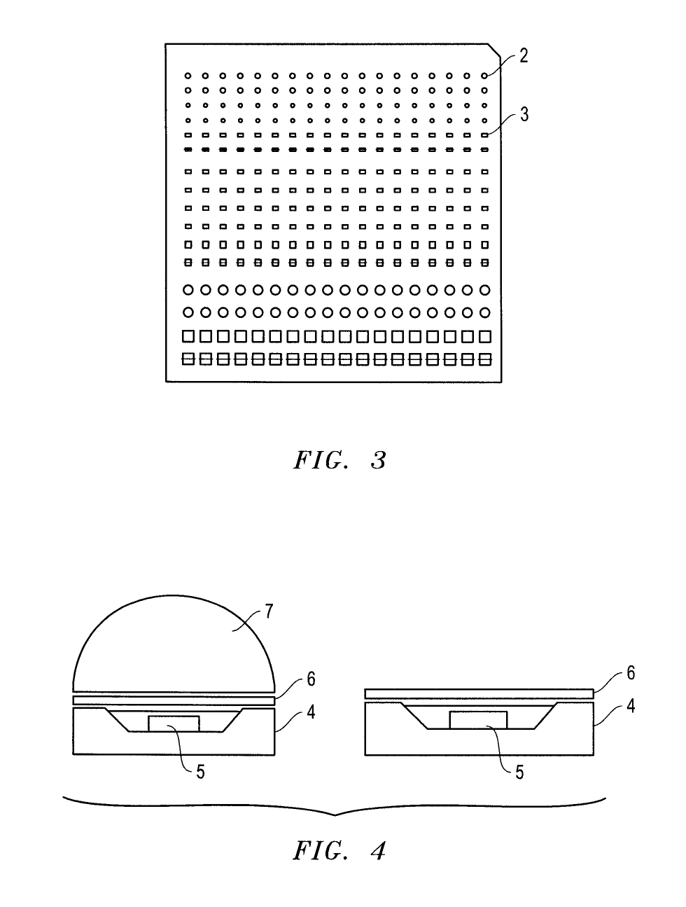

By way of example, FIG. 3 illustrates a sheet of clear soda lime or glaverbel float glass that is coated with a selectively applied inorganic thin film optical coating, which may comprise a dichroic coating. Prior to coating the glass with the inorganic thin film optical coating, a selective release agent coating is applied to the glass. The noted area 2 comprises the selectively applied release agent, and the background area 3 does not include release agent. Once the inorganic thin film optical coating has been applied, the coating disposed in the noted area 2 is removable while the coating disposed in the background area 3 is adhered to the glass. The inorganic thin film optical coating disposed in the noted area 2 is selectively removed and bonded to the LEDs. In one embodiment of the present invention, the coating process is repeated to stack multiple coatings of the same or different thin film optical coating compositions on the same LEDs.

By way of a further example, FIG. 4 illustrates an LED with a bonded dichroic coating and a resin encapsulant in accordance with the present disclosure. As shown in FIG. 4, the LED consists of a plastic or ceramic package 4, a light emitting die 5, a bonded dichroic coating 6, and a protective resin encapsulant 7. In some embodiments the resin encapsulant 7 contains near infrared absorbers, light stabilizers, and/or visible color correcting dyes or pigments. In other embodiments, the ceramic package 4 is opaque and is used and defined as a package that emits less than 1% of the total output. In other embodiments, the light emitting die 5 is created by combining a phosphor with a blue LED. The light emitting die 5 can be created by any of the suitable manufacturing techniques known in the art, using materials such as indium gallium nitride, zinc selenide, gallium(III) phosphide, aluminum gallium indium phosphide, gallium arsenide phosphide, or any other suitable material known in the art.

The resin encapsulant 7 can be comprised of any optically transparent polymers known in the art such as, but not limited to, transparent polyester, polyurethane, polyepoxide, poly(methyl methacrylate) (PMMA), or silicone. The resin encapsulant 7 may be cured using any method known in the art, such as thermal or ultraviolet (UV) curing.

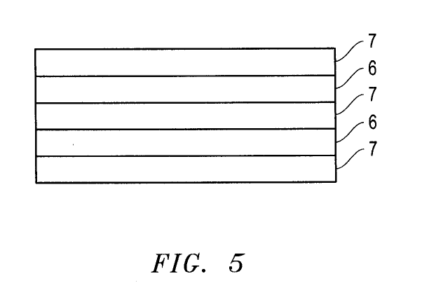

FIG. 5 illustrates a further embodiment of the disclosed inorganic thin film optical coating construction manufactured in accordance with the teachings of the present invention. In some embodiments of the present invention, the coating process is repeated to stack multiple coatings of the same or different thin film optical coating compositions on the same LEDs. The resin encapsulant 7 is bonded between alternating layers of the thin film optical coating 6. In one embodiment of the present invention, the thin film optical coating 6 is coated directly onto the resin encapsulant layers 7. In other embodiments the resin encapsulant 7 contains near infrared absorbers, light stabilizers, and/or visible color correcting dyes or pigments.

The inorganic thin film optical coatings exhibit high reflection in the red and near infrared regions of the electromagnetic spectrum. In one at least embodiment, the inorganic thin film optical coatings, which may include dichroic coatings, have a selective rejection band anywhere between approximately 600 nm and 1200 nm, and a high selective transmission band anywhere between approximately 400 nm and 600 nm of the electromagnetic spectrum.

In some embodiments the resin encapsulant 7 contains near infrared absorbers, light stabilizers, and/or visible color correcting dyes or pigments. The dyes or pigments may comprise organic or inorganic infrared absorbers. In some embodiments, the infrared absorbers exhibit high absorbance in the red and near infrared regions of the electromagnetic spectrum. In at least one embodiment, the infrared absorbers preferably have an absorption peak between approximately 650 nm and 1200 nm and limited absorption between approximately 400 nm and 600 nm of the electromagnetic spectrum. While the near infrared absorbers may comprise any suitable absorbers known in the art, the absorbers are preferably a metal dithiolene, a rylene, a porphyrin, a phthalocyanine, a naphthalocyanine, or some combination thereof. Phthalocyanines and naphthalocyanines are particularly well-suited for use because of their stability at high temperatures. The infrared absorbers are preferably purified to substantially 99 percent using any suitable technique known in the art, such as, but not limited to, recrystallisation or column chromatography. Otherwise, failure to properly purify the infrared absorbers may inhibit the curing of the resin encapsulant 7 and/or reduce the thermal stability of the LEDs. This may result in a loss of absorbance and/or a yellow color shift over the operating life of the LEDs.

It will be appreciated by those skilled in the art that changes could be made to the embodiments described above without departing from the broad inventive concept thereof. It is understood, therefore, that the invention disclosed herein is not limited to the particular embodiments disclosed, but it is intended to cover modifications within the spirit and scope of the present invention as defined by the appended claims.

What is claimed is:

1. A night vision assembly, comprising:
one or more light emitting diodes; and
one or more inorganic thin film optical coatings applied to a surface of the one or more light emitting diodes.

2. The night vision assembly of claim 1, further comprising one or more protective resin encapsulants encapsulating the one or more inorganic thin film optical coatings.

3. The night vision assembly of claim 2, wherein the protective resin encapsulants contain visible absorbers, near infrared absorbers, or a combination of visible and near infrared absorbers.

4. The night vision assembly of claim 1, wherein the one or more light emitting diodes are coated with visible absorbers, near infrared absorbers, or a combination of visible and near infrared absorbers.

5. The night vision assembly of claim 1, wherein the one or more inorganic thin film optical coatings are bonded directly to or coated on the top surface of the one or more light emitting diodes.

6. The night vision assembly of claim 3 or 4, wherein the one or more inorganic thin film optical coatings and near infrared absorbers substantially absorb or reflect energy between 600 nm and 1200 nm of the electromagnetic spectrum.

7. The night vision assembly of claim 2, wherein the one or more inorganic thin film optical coatings and one or more resin encapsulants are configured to transmit energy between 400 nm and 600 nm of the electromagnetic spectrum.

8. The night vision assembly of claim 2, wherein the one or more resin encapsulants comprise one or more of the following: transparent polyester, polyurethane, polyepoxide, poly (methyl methacrylate) (PMMA), or silicone.

9. The night vision assembly of claim 2, wherein the one or more resin encapsulants are bonded between alternating layers of the one or more inorganic thin film optical coatings.

10. A method for manufacturing a night vision assembly, comprising:
applying one or more inorganic thin film optical coatings onto a glass;
removing said one or more inorganic thin film optical coatings from the glass;
transferring said one or more inorganic thin film optical coatings to one or more light emitting diodes; and
bonding said one or more thin film optical coatings to the one or more light emitting diodes.

11. The method of claim 10, further comprising molding one or more encapsulants onto the one or more inorganic thin film optical coatings.

12. The method of claim 11, further comprising incorporating visible absorbers, near infrared absorbers, or a combination of visible and near infrared absorbers into the one or more encapsulants.

13. The method of claim 10, further comprising coating the one or more light emitting diodes with visible absorbers, near infrared absorbers, or a combination of visible and near infrared absorbers.

14. The method of claim 10, wherein the one or more inorganic thin film optical coatings are bonded directly to or coated on the top surface of the one or more light emitting diodes.

15. The method of claim 12, wherein the one or more inorganic thin film optical coatings and near infrared absorbers substantially absorb or reflect energy between 600 nm and 1200 nm of the electromagnetic spectrum.

16. The method of claim 13, wherein the one or more inorganic thin film optical coatings and near infrared absorbers substantially absorb or reflect energy between 600 nm and 1200 nm of the electromagnetic spectrum.

17. The method of claim 11, wherein the one or more inorganic thin film optical coatings and one or more encapsulants are configured to transmit energy between 400 nm and 600 nm of the electromagnetic spectrum.

18. The method of claim 11, wherein the one or more encapsulants comprise one or more of the following: transparent polyester, polyurethane, polyepoxide, poly (methyl methacrylate) (PMMA), or silicone.

19. The method of claim 11, wherein the one or more encapsulants are bonded between alternating layers of the one or more inorganic thin film optical coatings.
